(19) United States
(12) Patent Application Publication
(10) Pub. No.: US 2004/0031966 A1
(43) Pub. Date: Feb. 19, 2004

(54) Organic photonic integrated circuit using a photodetector and a transparent organic light emitting device

(76) Inventors: Stephen R. Forrest, Princeton, NJ (US); Peter Peumans, Princeton, NJ (US); Michael Hack, Lambertville, NJ (US); Vladimir Bulovic, Lexington, MA (US)

Correspondence Address: KENYON & KENYON, ONE BROADWAY, NEW YORK, NY, 10004, US

(21) Appl. No.: 10/254,265

(22) Filed: Sep. 25, 2002

Related U.S. Application Data
(63) Continuation-in-part of application No. 10/219,760, filed on Aug. 16, 2002.

(51) Int. Cl. H01L 31/12

(52) U.S. Cl. 257/79

(57) ABSTRACT

A device is provided that includes an organic light emitting device, and a photodetector disposed adjacent the organic light emitting device, the photodetector being adapted to detect light emitted by the organic light emitting device. The photodetector may share a transparent electrode with the organic light emitting device. The photodetector may be organic or inorganic.

This is a continuation-in-part of application Ser. No. 10/219,760, filed Aug. 16, 2002, the subject matter of which is incorporated herein.

### FIELD OF THE INVENTION

The present invention generally relates to an organic light emitting device. More particularly, the invention relates to a device that includes both an organic light emitting device and a photodetector.

### BACKGROUND OF THE INVENTION

Organic materials have been proposed for many applications in electronics and opto-electronics due to their low cost and simple device fabrication processes. Many individual devices based on organic materials have been demonstrated in the past two decades.

Organic light emitting devices (OLEDs), which make use of thin films that emit light when excited by electric current, have become an increasingly recognized technology for applications such as flat panel displays. Popular OLED configurations include double heterostructure, single heterostructure, and single layer, as described in PCT Application WO 96/19792, which is incorporated herein by reference.

Recently, progress in OLED transistors, photovoltaic cells, and photodetectors has drawn considerable interest in the field of organic electronics. The use of organic materials in OLED transistors, photovoltaic cells and photodetectors is motivated by a number of advantageous properties. For example, in photodetection, the low index of refraction allows for the efficient coupling of light into devices, and typical optical absorption lengths of ˜500Å allow for the realization of ultra-thin and high-bandwidth devices. These devices can be deposited on a variety of substrates including low-cost, flexible foils, thereby forming a basic building block for molecular organic photonic integrated circuits. Such devices may be used as an input device in an organic transistor circuit in widespread applications.

### SUMMARY OF THE INVENTION

A device is provided that includes an organic light emitting device, and a photodetector disposed adjacent the organic light emitting device, the photodetector being adapted to detect light emitted by the organic light emitting device. The photodetector may share a transparent electrode with the organic light emitting device. The photodetector may be organic or inorganic.

### BRIEF DESCRIPTION OF THE DRAWINGS

FIG. 1 shows a cross sectional view of a device having an organic photodetector disposed over a transparent electro-phosphorescent organic light emitting device, in accordance with a first embodiment of the present invention;

FIG. 2 shows a cross sectional view of a device having an organic photodetector disposed to the side of a transparent electro-phosphorescent organic light emitting device, in accordance with a second embodiment of the present invention;

FIG. 3 shows a cross sectional view of a device having an organic photodetector disposed under a transparent electro-phosphorescent organic light emitting device, in accordance with a third embodiment of the present invention;

FIG. 4 shows a cross sectional view of a device having an organic photodetector disposed over a portion of a transparent electro-phosphorescent organic light emitting device, in accordance with a fourth embodiment of the present invention;

FIG. 5 shows a switching device for enhancing bistability of an embodiment of the present invention;

FIG. 6 shows a brightness control circuit for an embodiment of the present invention;

FIG. 7 shows a top view of a device fabricated in accordance with an embodiment of the present invention;

FIG. 8 shows the current density versus voltage characteristic of devices using different types of first electrodes, in accordance with an embodiment of the present invention;

FIG. 9 shows the relationship between photodetector current and organic light emitting device (OLED) voltage at various photodetector drive voltages for an embodiment of the invention;

FIG. 10 shows the relationship between photodetector current and OLED drive voltage and the relationship between OLED bottom emission power and OLED drive voltage at various photodetector drive voltages for an embodiment of the present invention;

FIG. 11 shows: (1) the relationship between photodetector current (I_{PD}) and photodetector drive voltage (V_{PD}) plus resistor voltage (V_{R}); and (2) the relationship between resistor voltage (V_{R}) photodetector drive voltage (V_{PD}) plus resistor voltage (V_{R}), both at various OLED drive voltages, in accordance with an embodiment of the present invention;

FIG. 12 shows the relationship between OLED drive voltage and gate-source voltage of a transistor (V_{gs}) and the relationship between OLED bottom emission power and V_{gs} for an embodiment of the present invention; and

FIG. 13 shows the OLED bottom emission power of an embodiment of the present invention as a function of time at various source voltages of a transistor.

### DETAILED DESCRIPTION

An integrated device includes an organic photodetector disposed adjacent to an organic light emitting device (OLED). This integrated device has potential applications in automatic brightness control, image retaining displays and other photonic logic applications.

One application is automatic brightness control. Conventional OLEDs are subject to potential degradation during their life-spans. Each OLED, however, may have a degradation rate different from that of other OLEDs. Some devices, such as a display screen, may include many individual OLEDs and require that most of these OLEDs are emitting a specific amount of light for satisfactory operation. When too many of the OLEDs have degraded, the device may be considered non-functional. Thus, the degradation of only a few OLEDs may make it necessary to replace the entire device, and the useful life of the larger device may be determined by the fastest degrading OLED components. The automatic brightness control provided by embodiments of the present invention compensates for such degradation by increasing the voltage across devices that no longer emit as intensely at the originally specified voltage.

According to embodiments of the present invention, each OLED would be turned on in sequence when the display is initially powered on in a pixelated display application. The intensity of each OLED, or of selected OLEDs (for example, one of each color in a full color display) may be measured by a corresponding photodetector. Measurements may be stored in a look-up table. Subsequently, the intensity of light of each OLED may again be measured and adjusted to compensate for any differences from the original measurements. Such monitoring may be continuous, or may be performed at certain times, such as upon power-up, periodically, or upon a prompt. In this way, the device may allow each pixel of the display to achieve optimal and stable luminescence throughout the display lifetime.

Furthermore, in accordance with embodiments of the present invention, a bistable device may be achieved with a transistor providing feedback to the integrated device. In its “HIGH” state, the photodetector may be used to turn on a transistor (for example, by generating an appropriate bias voltage across a resistor), which, in turn, provides current to the OLED, thereby maintaining the device in the “HIGH” state. In its “LOW” state, the photodetector does not generate enough voltage across the resistor to turn on the transistor, so the transistor is off and little or no current is provided to the OLED. Accordingly, the device is maintained in its “LOW” state. In this way, bistability of the device is achieved.

As used herein, the term “adjacent to” is broadly defined to include various positions of the photodetector with respect to the OLED. In accordance with one embodiment, the photodetector may be disposed over the OLED. The term “over” is used to indicate a layer that is farther away from a substrate of a device. In accordance with another embodiment, the photodetector may be disposed under the OLED. The term “under” is used to indicate a layer that is closer to a substrate of a device. The photodetector may also be disposed to the side of the OLED. According to another embodiment, the photodetector may be disposed over or under only a portion of the OLED.

Furthermore, as used herein, the term “over” allows for intervening layers. For example, if a second layer is disposed “over” a first layer, there may be a third layer deposited in between the first and second layers. As used herein, the term “on top of” does not allow for intervening layers. For example, if a second layer is deposited “on top of” a first layer, the second layer is in direct physical contact with the first layer, and no layer is deposited in between the first and second layers.

As used herein, a “transparent” layer is a layer that transmits some or all of the light incident upon the layer.

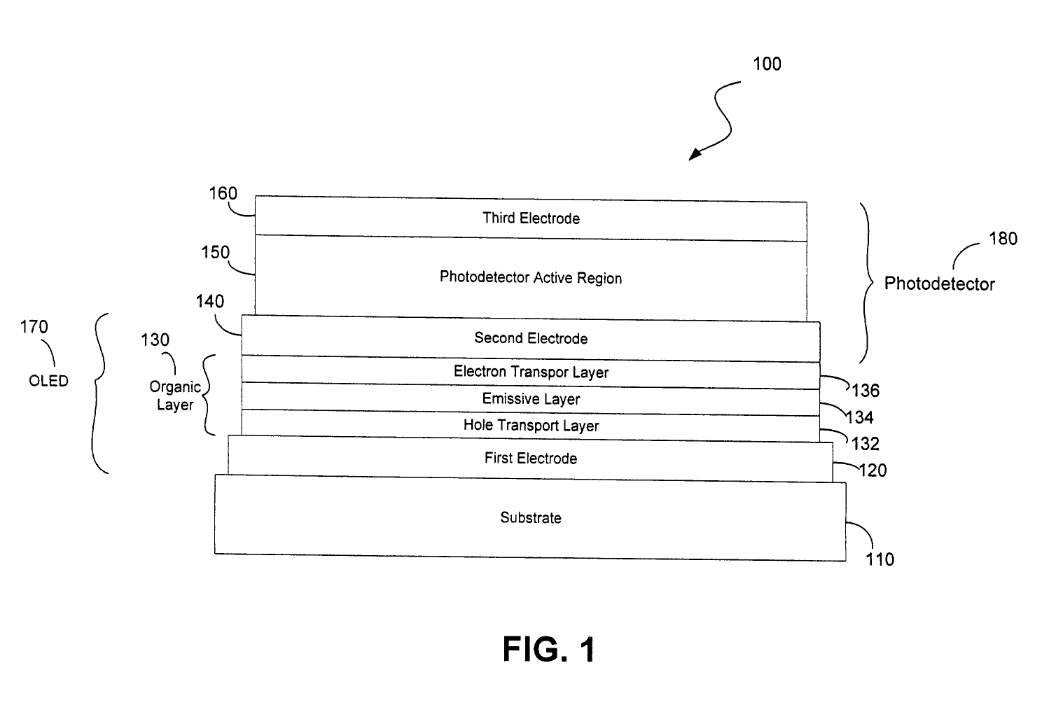

FIG. 1 shows a cross sectional view of a device having an organic photodetector disposed over a transparent electro-phosphorescent organic light emitting device, in accordance with a first embodiment of the present invention. Device 100 may be fabricated on a substrate 110 and may include a first electrode 120, an organic layer 130, a second electrode 140, a photodetector active region 150, and a third electrode 160. First electrode 120, organic layer 130, and second electrode 140 may comprise an organic light emitting device (OLED) 170. Organic layer 130 may further comprise a first hole transport layer 132, an emissive layer 134, and an electron transport layer 136 when used in a double heterostructure as shown in FIG. 1. Organic layer 130 may, however, use other combinations of layers known to the art, such as single heterostructure, single layer, and the like. Organic layer 130 may also include other layers known to the art, such as blocking layers. Second electrode 140, photodetector active region 150 and third electrode 160 may comprise a photodetector 180. Photodetector 180 may further comprise other layers known to the art, such as transport layers, and blocking layers. In the embodiment illustrated in FIG. 1, OLED 170 and photodetector 180 may share second electrode 140.

OLED 170 refers to an organic light emitting device with a transparent top electrode. OLED 170 emits light when it is “ON.” Some of the light is transmitted through second electrode 140. At least some of the transmitted light is then absorbed by photodetector 180.

Photodetector 180 generates carriers in response to the absorbed light, which may then be measured to provide an indication of the intensity of light emitted by OLED 170. The amount of generated carriers may depend on the bias voltage applied over photodetector 180.

Substrate 110 may be any suitable substrate known to the art, including glass, plastic, or ceramic. Substrate 110 may also be either flexible or inflexible. Substrate 110 may be transparent or opaque.

First electrode 120 deposited on a substrate 110 preferably functions as an anode, but may function as a cathode. First electrode 120 may be any suitable material or combinations of materials known in the art. First electrode 120 and substrate 110 may be sufficiently transparent to create a bottom emitting device. Where first electrode 120 is transparent, a preferred material is indium-tin-oxide (ITO). The order of organic layers may be adjusted when the first electrode is adapted to function as a cathode. For example, the positions of the hole transporting layer and electron transporting layer may be switched.

In the double hetero-structure configuration shown in FIG. 1, organic layer 130 may further comprise first hole transport layer 132, emissive layer 134 and first electron transport layer 136. Organic layer 130 may also have other configurations known to the art, such as single hetero-structure or single layer. Generally, organic layer 130 may include any organic material or combination of organic materials that emit light when a suitable voltage is applied between first electrode 120 and second electrode 140. Examples of suitable materials include 4,4′-[N-(1-naphthyl)-N-phenyl-amino]biphenyl (α-NPD) for first hole transport layer 132, 7 wt % fac tris(2-phenylpyridine)iridium [Ir(ppy)₃] doped with a 4,4′-dicarbazole-biphenyl (CBP) host for emissive layer 134, and tris(8-hyroxyquinoline)aluminum (Alq₃) or cyano-poly(p-phenylene)vinylene (CN-PPV) for electron transport layer 136.

OLED 170 may further include other layers. Such layer include blocking layers (not shown), adapted to block charge carriers from moving out of emissive layer 134. Such blocking layers are described in more detail in patent application Ser. No. 10/173,682 to Forrest (filed Jun. 18, 2002), Atty. Docket No. 10020-23301, which is incorporated by reference in its entirety. Another such layer is a buffer layer disposed beneath second electrode 140, adapted to protect underlying organic layer 130 during the deposition of second electrode 140. An example of a buffer layer material is bathcuproine (BCP). The OLEDs may be comprised of polymeric OLEDs (PLEDs). Examples of PLEDs are disclosed in U.S. Pat. No. 5,247,190 to Friend et al., which is incorporated herein by reference in its entirety.

Any organic layers of the various embodiments may be deposited by methods known to the art, including thermal evaporation or organic vapor phase deposition (OVPD), such as that described in U.S. Pat. No. 6,337,102 to Forrest et al, which is incorporated by reference in its entirety. Where a polymer organic layer is used, spin-on, spray-on, and ink-jet deposition methods may be preferred.

Second electrode 140 may be disposed over electron transport layer 136. Second electrode 140 may be sufficiently transparent that light emitted to OLED 170 may be detected by photodetector 180. Preferably, second electrode 140 acts as a cathode for OLED 170. A preferred second electrode 140 includes a layer of Mg:Ag alloy, deposited over organic layer 130 and a layer of ITO deposited over the layer of Mg:Ag.

Photodetector active region 150 may be disposed over second electrode 140. Photodetector active region 150 may generate carriers in response to the light emitted by organic layer 130. The amount of generated carriers may be dependent on the bias applied voltage over photodetector 180. One suitable structure for photodetector active region 150 is alternating layers of Cu-phthalocyanine (CuPc) and 3,4,9,10-perylenetetracarboxylic bis-benzimidazole (PTCBI). Sixteen alternating layers, eight alternating layers, or another number of layer may be used. In embodiments of the present invention, the above mentioned organic alternating multiplayer photodetectors may provide strong optical absorption and relatively high carrier velocities. It would be apparent to one skilled in the art, however, that other photodetector combinations may be used, so long as they may be adapted to detect light.

An highly efficient photodetector active region 150 that absorbs most as all of the light incident upon it may be used for certain applications, such as high contrast displays, where reflection from photodetector 180 transmitted back into OLED 170 is not desired. Alternatively, an inefficient photodetector active region 150 may be used, for example, one that absorbs 5% or less of the light passing through. An inefficient photodetector active region 150, used in conjunction with a reflective third electrode, allows light to be reflected back into OLED 170 and subsequently to a viewer, thereby increasing efficiency.

In the embodiment shown in FIG. 1, photodetector 180 may further comprise other layers, such as a carrier transport layer, a blocking layer, and / or a buffer layer. For example, a second hole transport layer may be disposed between second electrode 140 and photodetector active region 150. The second hole transport layer may be a p-doped semiconductor material. For example, 4,4′,4″-tris(3-methyl-phenyl-phenyl-amino)triphenylamine (MTDATA) doped with 2 wt % tetrafluoro-tetracyano-quinodimethane (F₄-TCNQ) [MTDATA:F₄-TCNQ(50:1)] is a suitable p-doped organic semiconductor material for the second hole transport layer.

A buffer layer 155 may be disposed between third electrode 160 and photodetector active region 150. Buffer layer 155 protects photodetector active region 150 from damage during the fabrication of third electrode 160. It has been found that the addition of such a buffer layer 155 may advantageously reduce the dark current of photodetector 180.

Third electrode 160 may be disposed over photodetector active region 150. Third electrode 160 may be any suitable material or combination of materials known to the art. For example, aluminum (Al) or other materials known to the art may be used as third electrode 160. For a top emitting device, third electrode 160 may be a transparent electrode. For a bottom emitting device, third electrode 160 is preferably reflective, so that light may be reflected back toward the viewer. For high contrast bottom emitting displays, third electrode 160 and photodetector active region 150 preferably absorb most or all of the light incident upon them from OLED 170. For fully transparent devices, all electrodes may be transparent.

The specific materials described herein for the various layers are exemplary in nature, and other types of OLEDs and photodetectors may also be used. Many of the specific layers described, such as separate transport layers and blocking layers, may be omitted based on design, performance, and cost considerations.

In one embodiment, an inorganic photodetector may be used in conjunction with an organic light emitting device, such that the inorganic photodetector is disposed adjacent to the organic light emitting device and is adapted to detect light emitted by the OLED. The inorganic photodetector may be based on amorphous silicon, polycrystalline silicon, or other photosensitive semiconductor, or combinations thereof. The photodetector may be fabricated on a semiconductor backplane. For example, the photodectector may be an inorganic device, such as a silicon diode, fabricated on a silicon backplane, with an organic light emitting device disposed over the photodetector. Such an embodiment may have advantages because circuitry may also be fabricated on the silicon backplane. Other configurations using an inorganic photodetectors may also be used. Other substrate materials and other inorganic photodetectors may be used.

Conventional OLEDs used in OLED-based displays typically degrade in their luminous efficiency over time. Device 100, according to embodiments of the present invention, allows for an in-situ monitoring method for each OLED pixel. Thus, device 100 may determine the amount of light emitted by OLED 170. Thus, the current through OLED 170 can be adjusted to optimize its brightness.

As illustrated in FIG. 1, OLED 170 and photodetector 180 are fabricated in sequences on the same substrate 110. Alternatively, OLED 170 and photodetector 180, as well as other embodiments of the invention, may be grown on separate substrates for subsequent lamination or other attachment.

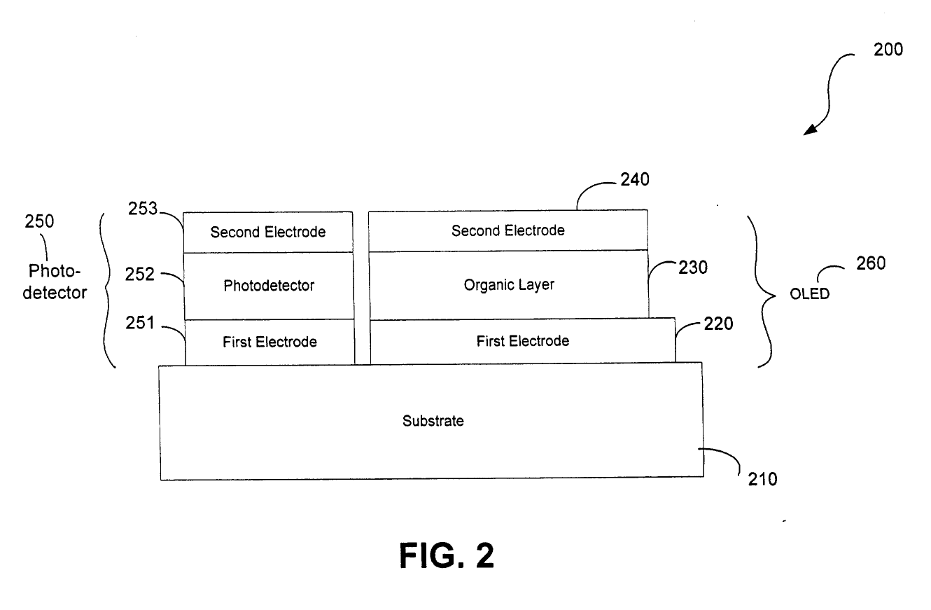

FIG. 2 shows a cross sectional view of a device 200 having an organic photodetector disposed to the side of an organic light emitting device, in accordance with a second embodiment of the present invention. Device 200 may include a first electrode 220 disposed over a substrate 210, an organic layer 230, a second electrode 240, and a photodetector 250. First electrode 220, organic layer 230 and second electrode 240 may comprise an OLED 260. OLED 260 may comprise other layers as described above with respect to FIG. 1, such as transport layers (not shown), and blocking layers (not shown). Photodetector 250 may be disposed to the side of OLED 260. Photodetector 250 may be further comprised of a first electrode 251, a photodetector active region 252 and a second electrode 253. To simplify fabrication, either the bottom electrodes or the top electrodes may be (but is not necessarily) shared by photodetector 250 and OLED 260. Put another way, first electrode 220 and first electrode 251 may be connected to form a single first electrode, or second electrode 240 and second electrode 253 may be connected to form a single second electrode.

The materials that may be used to fabricate the various layers of device 200 are similar to those of device 100.

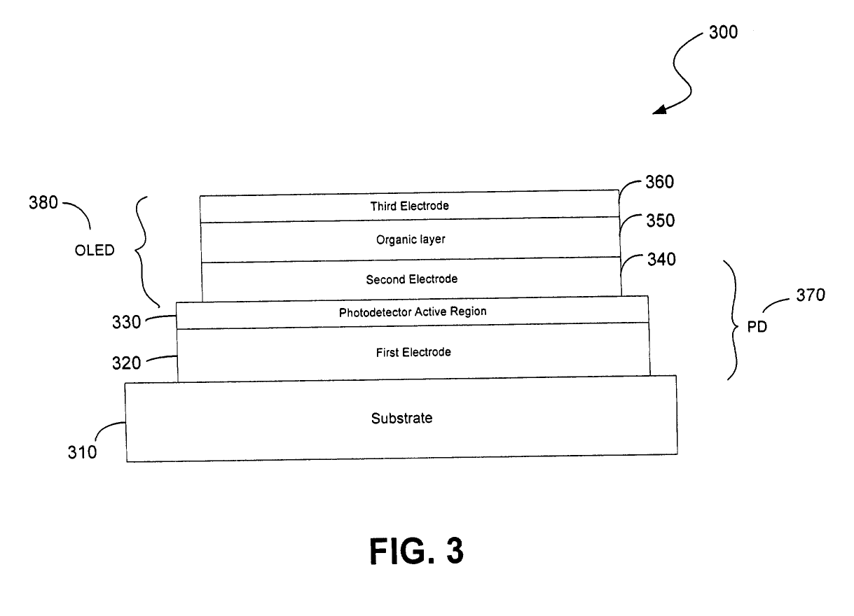

FIG. 3 shows a cross sectional view of a device having an organic photodetector disposed under an organic light emitting device, in accordance with a third embodiment of the present invention. Device 300 may include a first electrode 320 disposed over a substrate 310, a photodetector active region 330, a second electrode 340, an organic layer 350, and a third electrode 360. First electrode 320, photodetector active region 330 and second electrode 340 may comprise a photodetector 370. Second electrode 340, organic layer 350, and third electrode 360 may comprise a OLED 380.

Device 300, according to the third embodiment of the present invention, may be fabricated in a similar manner and from similar materials as the embodiment shown in FIG. 1, which is described below in greater detail. Device 300 may include layers not specifically shown, such as transport layers, blocking layers, and other layers as described with respect to the embodiment of FIG. 1.

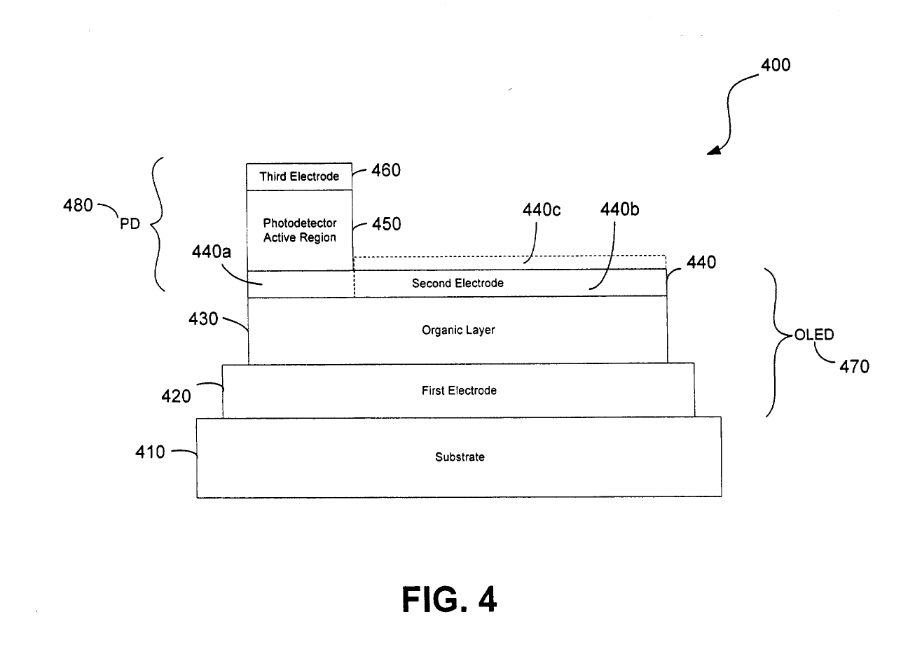

FIG. 4 shows a cross sectional view of a device having an organic photodetector disposed over a portion of an organic light emitting device, in accordance with a fourth embodiment of the present invention. Device 400 may include a first electrode 420 disposed over a substrate 410, an organic layer 430, a second electrode 440, a photodetector active region 450, and a third electrode 460. First electrode 420, emissive layer 430, and second electrode 440 may comprise an OLED 470. Photodetector active region 450, second electrode 440, and third electrode 460 may comprise a photodetector 480.

Device 400, according to the third embodiment of the present invention, may be fabricated in a similar manner and from similar materials as the embodiment of FIG. 1, which is described below in greater detail. Device 400 may include additional layers, such as transport layers, blocking layers, and other layers as described with respect to the embodiment of FIG. 1.

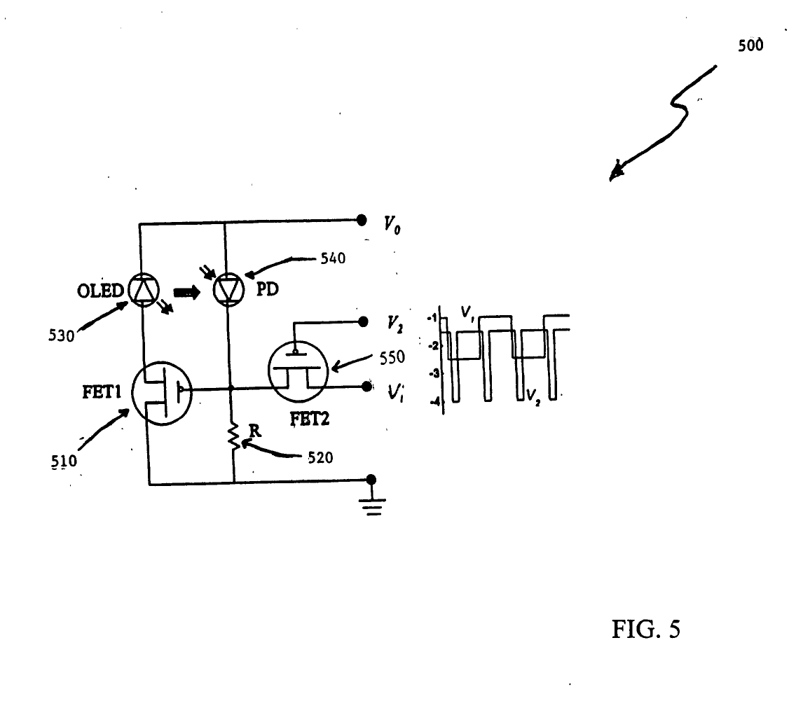

In one embodiment, photodetector 480 covers at most about ten percent of the top surface area of OLED 470. Preferably, photodetector 480 covers only a small fraction of the surface area of OLED 470, for example, about one percent of the top surface of OLED 470. Photodetector 480 only needs to absorb enough light to provide a sufficient voltage to alter the state of the controlling transistor. The fraction of the top surface area of OLED may be determined based on the photodetector sensitivity and the gain of an external circuit, an example of which is shown and described below in detail with reference to FIG. 5. By reducing the area covered by the photodetector 480, the amount of light absorbed by photodetector 480 is significantly reduced, and OLED 470 may emit more light, increasing the brightness of device 400. Thus, the structure shown in FIG. 4 may increase efficiency of device 400.

In this embodiment, electrode 440 may be a single electrode all fabricated by the same method. Or, electrode 440 may have two portions, a first portion 440a disposed under photodetector active region 450, and a second portion 440b that is not disposed under photodetector active region 440b. First portion 440a may be at least partially transparent, to allow light from organic layer 430 to reach photodetector active region 450. Particularly for bottom emitting OLEDs, second portion 440b may be reflective. The different properties of first portion 440a and second portion 440b may be achieved by first fabricating a transparent electrode, for example ITO/Mg:Ag, in both portions. Then, a reflective layer 440c may be deposited over portion 440b, either before or after photodetector 480 is fabricated. The different properties of first portion 440a and second portion 440b may also be achieved by fabricating different electrodes, for example a transparent ITO/Mg:Ag electrode for first portion 440a, and a reflective LiF doped with Al electrode for second portion 440b. Light emitted by organic layer 430 incident upon second portion 440b may be reflected back towards a viewer in a bottom emitting OLED, thereby increasing efficiency of device 400.

In another embodiment, a photodetector may be disposed under only a portion of the OLED. This embodiment may have a photodetector disposed under an OLED as illustrated in FIG. 3, but the photodetector may be much smaller than the OLED as shown in FIG. 4.

Each of the embodiments, including those illustrated in FIGS. 1-4, may be used in connection with a bistable switch. FIG. 5 illustrates a first bistable switching circuit 500 for an embodiment of the present invention. The bistability of an OLED 530 and a photodetector 540 may be achieved with the use of a transistor 510 and a resistor 520, as shown in circuit 500 of FIG. 5. In an example actually fabricated, an intrinsic p-type organic field effect transistor is used as transistor 510. There are two stable direct current (DC) operating points of this system: the “LOW” and “HIGH” states, which may be switched by a signal transmitted through a second transistor 550. Other circuits may be used to achieve the same result.

In the LOW state, OLED 530 does not emit light, so that the current passing through photodetector 540, I_{PD}, is solely its dark current. By choosing an appropriate resistance “R” for resistor 520, the gate voltage of transistor 510 may be selected such that, in the low state, the gate voltage is between the threshold voltage of transistor 510 and zero (V_{T1}<V^{l}_{g1}<0, where V_{T1} is the threshold voltage of T1 510, V_{g1}=−|I_{PD}|. R 520 is the gate voltage of transisitor 510, and the superscript “l” represents the LOW state). Hence, transistor 510 remains off to maintain the LOW state of OLED 530.

In the HIGH state, OLED 530 emits light that is directly coupled into photodetector 540 through the transparent cathode of OLED 530, which generates a photocurrent. The properties of photodetector 540 and resistor 520 may be selected such that this photocurrent results in a gate voltage for transistor 510 that is higher than the threshhold voltage of that transistor, V^{l}_{g1}<V_{T1}<0, where the superscript “h” represents the HIGH state, such that the HIGH state is maintained. Second transistor T2 550 may be adapted to provide pulses in order to toggle bistable switch 500 between HIGH and LOW states, as shown in FIG. 5. Circuits other than the one specifically illustrated in FIG. 5 may be used.

The dark current of photodetector 540 under reverse bias increases exponentially with √e,rad |V_{PD}|, where V_{PD} is the bias voltage of photodetector 540. In the LOW state, photodetector 540 may be subjected to a larger reverse bias because the voltage on photodetector 540 may be less than zero (V_{PD}=V_{S}−V_{g1}<0, where Vₛ<0 is the supply voltage). Thus, it is preferable to suppress the dark current.

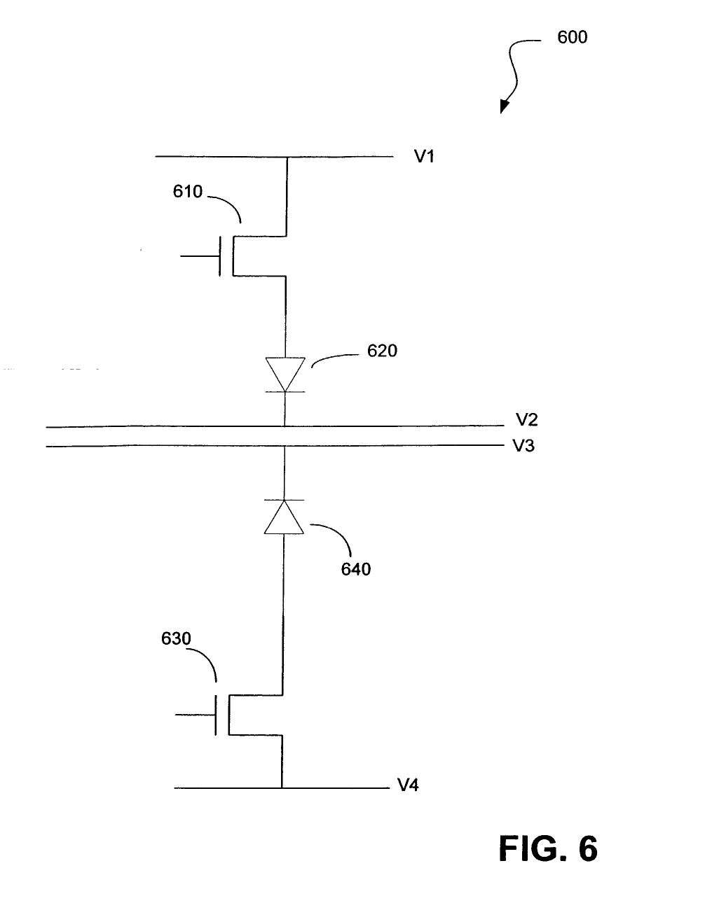

FIG. 6 shows a brightness control circuit 600 for an embodiment of the present invention. Circuit 600 includes a first transistor 610 with its drain connected to an OLED 620 and its source connected to a first reference voltage source, V1. OLED 620 is also connected to voltage V2. Circuit 600 also includes a second transistor 630 with its source connected to a voltage source V4, and its drain connected to a photodetector 640. Although not shown in FIG. 6, OLED 620 provides light to photodetector 640 as illustrated, for example, in FIGS. 1-4. A pulse may be provided at the gate of transisitor 630, and the voltage between V3 and V4 read by external circuits. The voltage difference between V3 and V4 provides a measure of the amount of light being emitted by OLED 620, because photodetector 640 is absorbing some of that light. External circuits may further be used to control the gate voltage of transistor 610 and/or the voltage difference between V1 and V2, to adjust the amount of light being emitted by OLED 620. The brightness of OLED 620 may therefore be maintained at a desired level.

The various circuits used in connection with the present invention may be external or internal. “Internal” as used to describe a circuit means that the circuit is locally fabricated on the same substrate as the OLED and photodetector, and is generally disposed on the substrate very close to the OLED with which the circuit is associated. “External” describes all other circuits, for example circuits that are connected to the OLED and photodetector by bus lines that run to the edge of an array of devices, and external circuits may be fabricated on a different substrate.

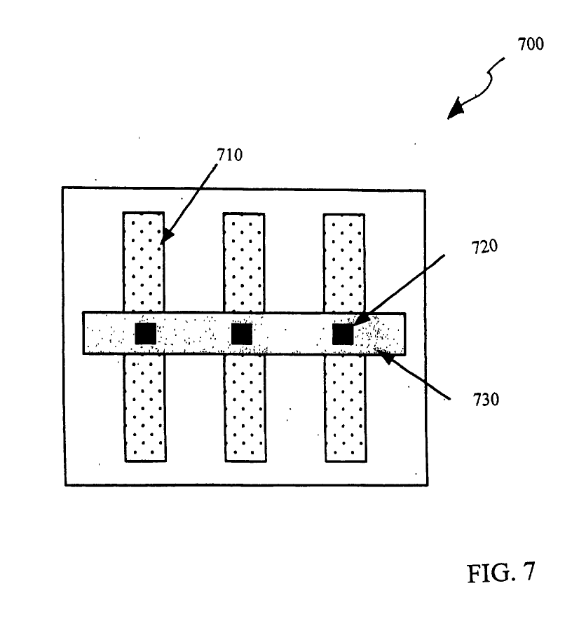

FIG. 7 shows a top view of a device 700 fabricated in accordance with an embodiment of the present invention. Device 700 includes a plurality of first electrode strips 710. A second electrode strip 730 is disposed perpendicularly over first electrode strips 710. A third electrode 720 is disposed over second electrode strip 730 at the intersection of first electrode strips 710 and second electrode strip 730. The organic layers of an OLED (not shown) may be disposed between first electrode strips 710 and second electrode strip 730. The photodetector active region (not shown) of a photodetector may be disposed between second electrode strip 730 and third electrode strip 720. FIG. 7 illustrates a particular configuration that was used for experiments, and it is understood that many configurations of electrodes, including conventional active matrix and passive matrix configurations, may be used in connection withembodiments of the present invention.

### EXPERIMENTAL

A device was fabricated in accordance with one embodiment of the present invention using the following materials and thicknesses:

| | |
|---|---|
| substrate: | commercially available glass substrate; |
| first electrode (anode): | 1500 Å, transparent, conducting ITO (with a |
| | sheet resistance of ˜40 ohms/square); |
| hole transport layer: | 400 Å, α-NPD; |
| emissive layer: | 200 Å, CBP: Ir(ppy)₃; |
| exciton blocking layer: | 80 Å, BCP; |
| electron transport layer: | 200 Å, Alq₃; |
| second electrode: | 120 Å, Mg—Ag/ITO; |
| p-doped layer: | 500 Å, MTDATA: F₄-TCNQ |
| photodetector active region: | 480 Å, 16 alternating layers of a 30 Å thick |
| | CuPc layer and a 30 Å thick PTCBI layer; |
| exciton blocking layer: | 150 Å, BCP; and |
| third electrode (cathode): | 1000 Å, Al. |

A glass substrate precoated with ITO was obtained. The ITO was patterned into 2-mm-wide stripes (710, FIG. 7) using conventional photolithography to form first electrodes as shown in FIG. 7 (electrodes 710). After solvent cleaning and exposure to O₂ plasma for 5 min, the substrate was immediately loaded into a vacuum system with a base pressure of <10⁻⁶ Torr. The α-NPD hole transport layer was then deposited onto the first electrode, followed by the emissive layer, the BCP exciton blocking layer, and the Alq₃ electron transport layer, in that order, all by vacuum thermal evaporation. The Mg:Ag layer was deposited through a shadow mask by coevaporation of Mg and Ag at a mass ratio of 20:1, resulting in a OLED area of 2×2 mm² (730, FIG. 7). The sample was immediately transferred through a load lock to a sputtering chamber with minimal exposure to the atmosphere. Then, a 500 Å thick layer of ITO was deposited through the same shadow mask by radio frequency magnetron sputtering in 5 mTorr of Ar at a power of 5 W at a rate of approximately 3 Å/min to complete a OLED structure. The Mg:Ag layer and the ITO layer formed an electrode similar to electrode 720 of FIG. 7.

After the ITO sputtering, the sample was transferred into an ultra-high vacuum organic molecular beam deposition chamber with a base pressure of 1×10⁻¹⁰ Torr. A layer of MTDATA doped with 2 wt % F₄-TCNQ was deposited onto the OLED cathode. This p-doped layer reduces the dark current of the photodetector while not compromising its quantum efficiency. The 16 alternating layers of the photodetector active region were then deposited by vacuum thermal evaporation, with the first CuPc layer in contact with the MTDATA of the p-doped layer. Then, the second blocking layer was deposited by vacuum thermal evaporation on top of the active region. The sample was transferred to a separate vacuum chamber. The Al cathode was evaporated at 1×10⁻⁶ Torr through a shadow mask with an opening of 0.8×0.8 mm² (720, FIG. 7) aligned to the center of the OLED. The resultant device appeared smiilar to those illustrated in FIG. 7, where electrode 730 is 2×2 mm.

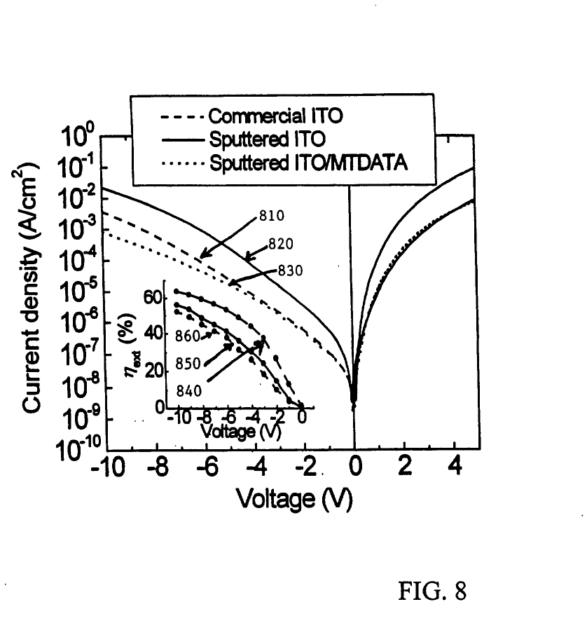

Devices similar to that described above were fabricated on different first electrodes including commercial ITO, a sputtered ITO, and a sputtered ITO doped with MTDATA. FIG. 8 illustrates the current density versus voltage characteristic of an embodiment of the invention when different types of first electrodes are used. Plot 810 illustrates the current density (A/cm²) for a device using commercial ITO. Plot 820 illustrates the current density (A/cm²) for a device having a photodetector deposited onto a sputtered ITO anode. Plot 830 illustrates the current density (A/cm²) for a device having a p-doped MTDATA layer inserted between first electrode and the first CuPc layer. When the active region of the photodetector is deposited onto the sputtered ITO anode used in the photonic integrated circuit, the reverse-bias dark current is higher than that obtained by using commercial ITO precoated on glass substrates. A dramatic decrease in the dark current is observed, however, when a p-doped MTDATA layer is inserted between first electrode and the first CuPc layer.

The inset of FIG. 8 illustrates the external quantum efficiencies, ηₑₓₜ, of these devices, which use different types of first electrodes, in accordance with an embodiment of the present invention. The external quantum efficiencies were measured using a λ=530 nm monochromatic beam of light. A calibrated Si photodetector is used to determine the intensity. Plot 840 illustrates the quantum efficiency for a device using commercial ITO. Plot 850 illustrates the quantum efficiency for a device having a photodetector deposited onto a sputtered ITO anode. Plot 860 illustrates the quantum efficiency for a device having a p-doped MTDATA layer inserted between first electrode and the first CuPc layer. The ηₑₓₜ of the photodetector with a sputtered ITO anode is lowered by <15% at −10 V than that using a commercial ITO anode, both corresponding to internal quantum efficiencies of close to 100% as the sputtered ITO is approximately 10% less transparent than the commercial ITO.

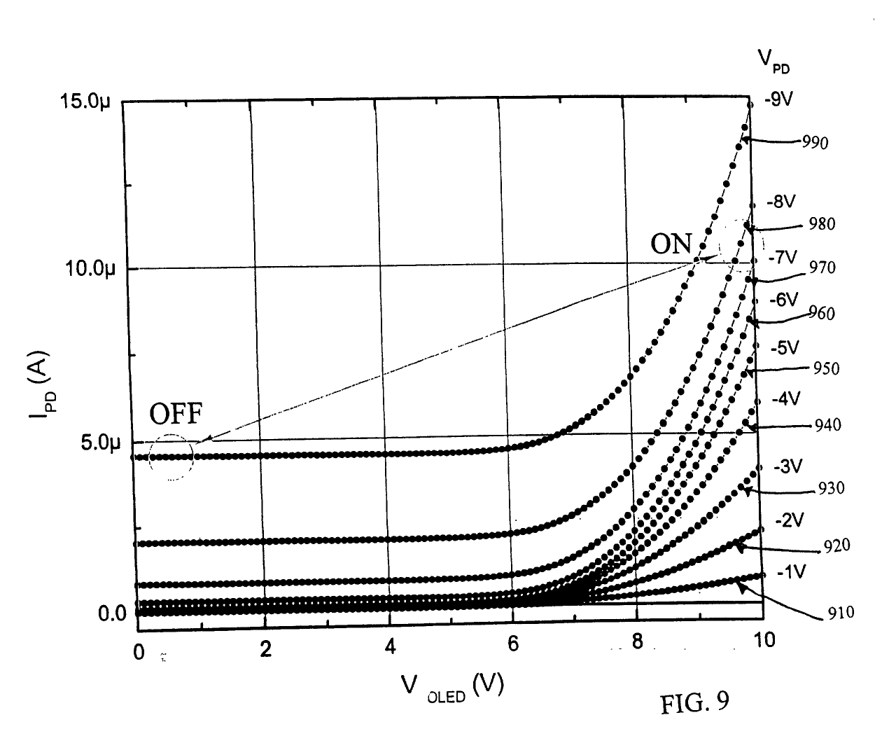

FIG. 9 shows the relationship between photodetector current (I_{PD}) and organic light emitting device (OLED) voltage (V_{OLED}) at various photodetector drive voltages (V_{PD}) for an embodiment of the invention. For example, plots 910, 920, 930, 940, 950, 860, 970, 980, and 990 illustrate changes in I_{PD} as V_{OLED} is increased when V_{PD} is set at −1V, −2V, −3V, −4V, −5V, −6V, −7V, −8V, and −9V, respectively. As illustrated by various plots in FIG. 6, I_{PD} is predominantly due to the detector dark current at low values of V_{OLED}. For example, I_{PD} is 600 pΛ at −1V and it increases to 4.5 μA at −9 V. Thus, at high V_{PD}, V_{OLED} must be increased to raise the photocurrent well above the dark current to turn on the device.

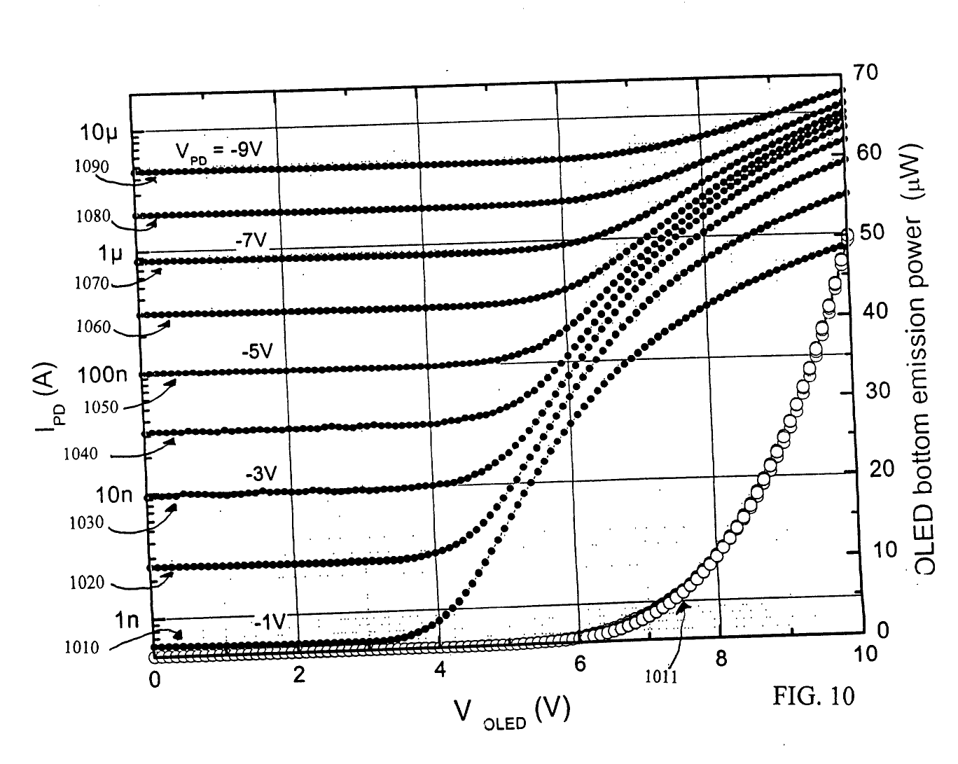

FIG. 10 shows the relationship between photodetector current (I_{PD}) and OLED drive voltage (V_{OLED}) and the relationship between OLED bottom emission power (αP_{bot}) and OLED drive voltage (V_{OLED}) at various photodetector drive voltages (V_{PD}) for an embodiment of the present invention. Plots 1010, 1020, 1030, 1040, 1050, 1060, 1070, 1080, and 1090 illustrate changes in αP_{bot} and I_{PD} as V_{OLED} is increased when V_{PD} is set at −1V, −2V, −3V, −4V, −5V, −6V, −7V, −8V, and −9V, respectively. Plot 1011 illustrates the photodetector response to light emitted by the OLED. As the amount of emitted light approaches zero at low voltages, the photodetector dark current establishes a floor which may be different for each photodetector bias voltage. For a discrete OLED, the luminance of the EL emission through the substrate is P_{bot}=2300±100 cd/m² (or 1.43 mW/cm²) at 10 V. This corresponds to a quantum efficiency of 2.2±0.1%. The ratio of the light emitted through the cathode to the light emitted through the substrate is α=0.50±0.05 for the OLED when the Mg—Ag layer has a thickness of 120 Å. This results in a total quantum efficiency of 3.3±0.2%.

With a photodetector integrated on top of the OLED, however, nearly 100% of the OLED top emission is coupled with the photodetector. As shown in FIG. 9, the photocurrent is approximately 10 μA with V_{PD}=−9V and V_{OLED}=10 V. This corresponds to an absorbed optical power density of 3.6 mW/cm² at λ=530 nm, while αP_{bot}=0.72 mW/cm² in this case, as best illustrated by plot 1090. This enhancement in the extraction efficiency of the OLED top emission is partially due to the higher refractive index of the photodetector organic layers (n≈1.8), which is better matched to that of the sputtered ITO than to that of air. It is also believed that microcavity effects may also contribute to the observed sensitivity enhancement due to the addition of the photodetector and its reflecting A1 cathode.

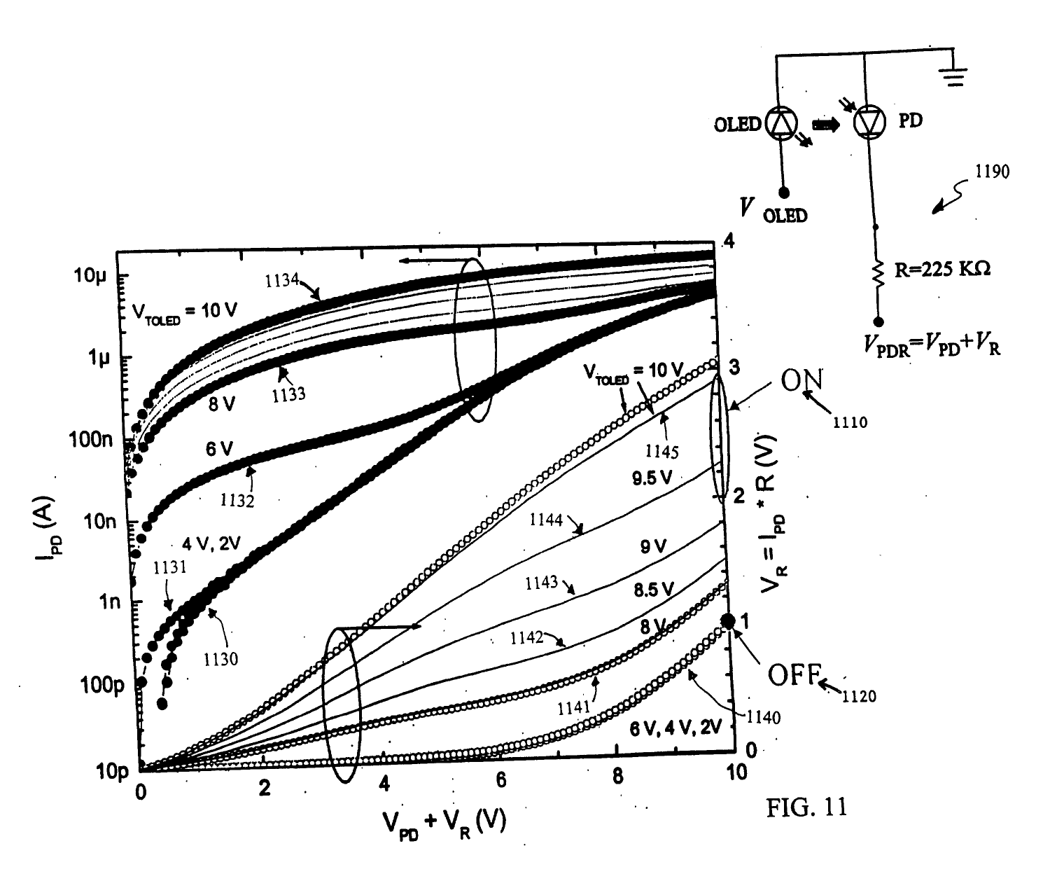

FIG. 11 shows: (1) the relationship between photodetector current (I_{PD}) and photodetector drive voltage (V_{PD}) plus resistor voltage (V_{R}); and (2) the relationship between resistor voltage (V_{R}) photodetector drive voltage (V_{PD}) plus resistor voltage (V_{R}), both at various OLED drive voltages, in accordance with an embodiment of the present invention. for circuit 1190. Plots 1130, 1131, 1132, 1133 and 1134 illustrate the relationship between I_{PD} and V_{PD}+V_{R} at V_{OLED}=2V, 4V, 6V, 8V, and 10V, respectively. Plots 1140, 1141, 1142, 1143, 1144, and 1145 illustrate the relationship between V_{R} and V_{PD}+V_{R} at V_{OLED}=6V, 8V, 8.5V, 9V, 9.5V, and 10V, respectively. FIG. 11 also shows the direct current (DC) operating points of two stable states of the fabricated device, in accordance with one embodiment of the present invention. In FIG. 11, range 1110 corresponds to the DC operating range of the fabricated device in its HIGH state, whereas range 1120 corresponds to the DC operating point of the fabricated device in its LOW state. Both transistors (550 and 610 in FIG. 6) are set at threshold voltages of V_{T1}=V_{T2}=−1.2 V. With Vₛ=−10 V, in the HIGH state V_{OLED}≈10 V, V_{PD}≈−7.5 V, V_{g1}≈−2.5 V<V_{T1}<0, and I_{PD}≈11 μA. With Vₛ=−10 V, in the LOW state V_{OLED}≈0 V, V_{PD}=−9.0 V, V_{g1}=−1.0 V>V_{T1}, and I_{PD}=4.5 μA. To test for proper circuit operation, R=225 kΩ is connected in series to the photodetector. The voltage drop across the resistor, V_{R}, is then measured as a function of Vₛ and V_{OLED}. As shown in FIG. 8, V_{R}≦1V when Vₛ=−10V and V_{OLED}≦2V; whereas 2V<V_{R}<3V with Vₛ=−10V and 9V<V_{OLED}<10V. As V_{R}=−V_{g1}, these two measures correspond to the LOW and HIGH states of the fabricated device, respectively.

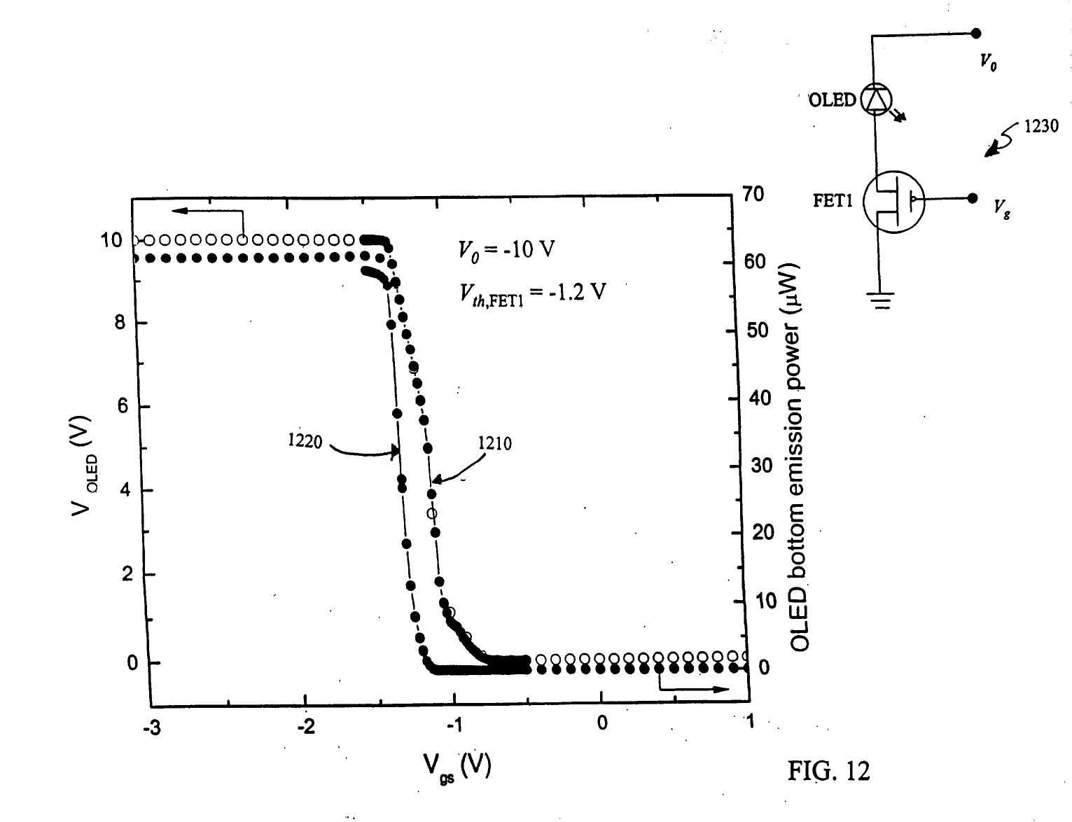

FIG. 12 shows the relationship between OLED drive voltage and gate-source voltage of a transistor (V_{gs}) and the relationship between OLED bottom emission power and V_{gs} for an embodiment of the present invention, for circuit 1230. Plot 1210 illustrates OLED drive voltage as a function of V_{gs}, whereas plot 1220 illustrates OLED bottom emission power as a function of V_{gs}. Both transistors (550 and 610 in FIG. 6) are set at threshold voltages of V_{T1}=V_{T2}=−1.2 V. FIG. 12 shows that the emission of an OLED may be switched between two states over a relatively narrow range of gate voltages.

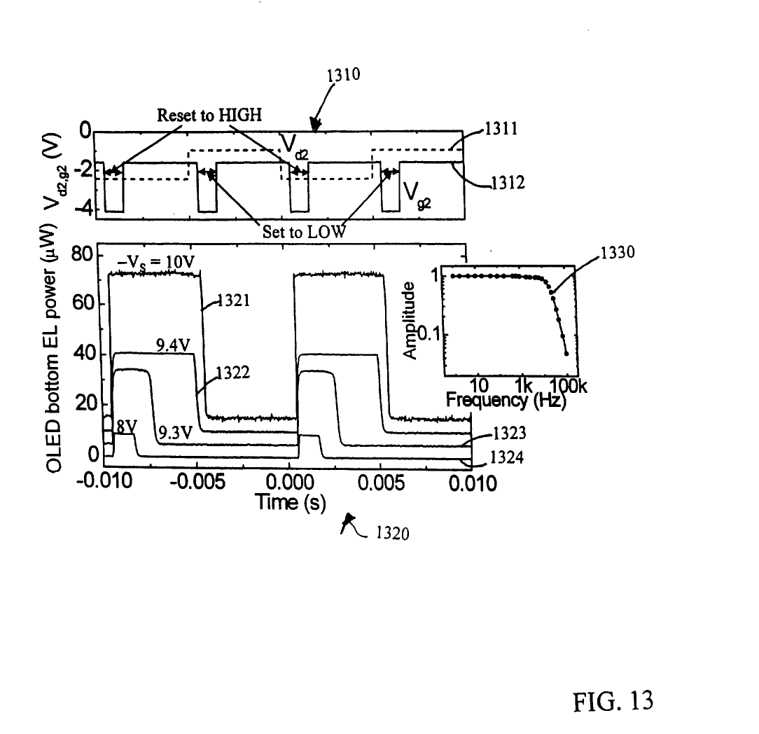

FIG. 13 illustrates the optical bistability of an embodiment of the present invention, as Vₛ was varied from 0 to −10 V. The input of V_{d2} and V_{g2} are shown in the upper panel 1310 of FIG. 13. Plot 1311 represents V_{d2}. Plot 1312 represents V_{g2}. The V_{g2} 1312 is delayed from V_{d2} 1311 by t_{d}=0.5 ms. Both V_{d2} and V_{g2} have a pulse width of t_{w}=1 ms. During the pulse window of V_{g2}, T2 is turned on, setting V_{g1} to −0.95 V or −2.45 V. This, in turn, sets the photonic integrated circuit to LOW or reset it to HIGH.

The waveforms of OLED bottom EL emission intensity at different Vₛ are shown in the lower panel 1320 of FIG. 13. Plots 1321, 1322, 1323, and 1324 illustrate OLED bottom EL emission intensity at Vₛ of −10V, 9.4V, 9.3V, and 8V. The waveforms are shifted vertically for clarity. At Vₛ=−8 V, OLED is on during the reset window. The HIGH state, however, is not stable as OLED turns off when T2 is switched off. As Vₛ is increased, OLED remains on for a brief period after T2 is switched off. At Vₛ=−9.4 V, the HIGH state is almost fully latched between two pulses. The stable HIGH state is clearly achieved with Vₛ=−10 V (i.e., OLED is turned on at the onset of the RESET window). OLED remains on until the onset of the SET window. At the onset of the SET window, OLED is turned off and remains off until the next RESET pulse. The RESET or SET windows can be as narrow as 60 ns to make the photonic integrated circuit switch between the two stable states.

The inset 1330 of the lower panel 1320 of FIG. 13 shows the frequency response of the relative peak-to-valley amplitude of the OLED bottom EL emission intensity. The 3 dB bandwidth is 25 kHz, and the roll-off is approximately −18 dB/decade due to the two poles of the circuit. This represents a lower limit of the actual bandwidth of the photonic integrated circuit. A Si photodetector used to measure the OLED emission intensity, which has a response time of ˜2 μs. Further, measurements of the capacitance of the circuit elements show that the frequency response is primarily limited by the RC time constant of ≧ 5 μs between the OLED resistance and the transistor capacitance.

The photonic integrated circuit, according to embodiments of the present invention, has potential applications in displays. Specifically, the photonic integrated circuit may have particular applications for devices in which bistable pixels can significantly reduce the bandwidth needed to refresh only those pixels whose image content changes between frames. Also the bistable photonic integrated circuit has similar applications to electronic paper, which may obtain an image from an external source, and store that image. The bistable photoic integrated circuit can be used in electronic blackboard, where an “image” is written with a light pen. The electronic blackboard may be erased by having a shorting transparent membrane over each pixel (e.g., ITO coated plastic) that when pressed, shorts across OLED, for example. Finally, given its digital response to a SET or RESET pulse the photonic integrated circuit can be used as a building block of photonic logic circuits. Taken alone, the integrated OLED/photodetector can be used in linear circuit applications such as automatic display brightness control and monitoring.

Embodiments of the present invention provide an organic photonic integrated circuit which enhances optical bistability by integrating a transparent OLED with an organic photodetector. The bistable circuit has a 3 dB bandwidth of 25 kHz. The organic photodetector is efficient over a broad spectral range from 450 nm to 750 nm. Therefore, it can be integrated with OLEDs of different colors to achieve bistability in full color display applications. The photonic integrated circuit can be electrically or optically reset using pulses as narrow as 60 ns. The photonic integrated circuit has potential applications in image-retaining displays and photonic logic circuits.

Several embodiments of the present invention are specifically illustrated and described herein. It will be appreciated, however, that modifications and variations of the present invention are covered by the above teachings and within the purview of the appended claims without departing from the spirit and intended scope of the invention.

What is claimed is:

1. A device comprising:
an organic light emitting device; and
a photodetector disposed adjacent the organic light emitting device, the photodetector being adapted to detect light emitted by the organic light emitting device.

2. The device of claim 1, wherein the photodetector is organic.

3. The device of claim 2, wherein the organic photodetector is disposed to the side of the organic light emitting device.

4. The device of claim 2, wherein the organic light emitting device and the organic photodetector share a transparent electrode.

5. The device of claim 4, wherein the organic photodetector is disposed over of the organic light emitting device.

6. The device of claim 4, wherein the organic photodetector is disposed under the organic light emitting device.

7. The device of claim 4, wherein the organic photodetector occupies at most ten percent of the surface area of the organic light emitting device.

8. The device claim 7, wherein the organic photodetector occupies at most one percent of the surface area of the organic light emitting device.

9. The device of claim 7, wherein:
the organic light emitting device further comprises:
a first electrode;
an organic layer electrically connected to the first electrode; and
a second electrode electrically connected to the organic layer, said second electrode having first and second portions; and
the photodetector further comprises:
a first portion of the second electrode;
a photodetector active region electrically connected to the first portion of the second electrode; and
a third electrode electrically connected to the photodetector active region.

10. The device of claim 9, wherein:
the second portion of the second electrode comprises:
the same materials as the first portion of the second electrode; and a reflective layer.

11. The device of claim 9, wherein:
the second portion of the second electrode comprises a reflective electrode that does not include the same layers as the first portion of the second electrode.

12. The device of claim 2, where all electrodes of the organic light emitting device are transparent, and all electrodes of the organic photodetector are transparent.

13. The device of claim 2, further comprising a feedback circuit adapted to detect a signal from the photodetector and control the organic light emitting device based on the signal.

14. The device of claim 13, wherein the feedback circuit is adapted to maintain a desired intensity of light emission from the organic light emitting device.

15. The device of claim 14, wherein the feedback circuit further comprising a transistor connected to the organic light emitting device and the organic photodetector, the transistor providing feedback between the organic light emitting device and the organic photodector to maintain bistability of the device.

16. The device of claim 4, wherein the transparent electrode is a transparent cathode.

17. The device of claim 16, wherein the transparent cathode comprises Mg:Ag.

18. The device of claim 4, wherein the organic light emitting device further comprises:
a first electrode disposed over a substrate;
an organic first hole transport layer disposed over the first electrode;
an organic emissive layer disposed over the first hole transport layer;
an organic electron transport layer disposed over the emissive layer; and
a second electrode disposed over the electron transport layer,
wherein the second electrode is the transparent electrode shared by the organic light emitting device and the organic photodetector.

19. The device of claim 18, wherein the photodetector further comprises:
the second electrode;
an organic photodetector active region disposed over the second hole transport layer; and
a third electrode disposed over the organic photodetector active region.

20. The device of claim 19, wherein the first electrode, the second electrode and the third electrode are transparent.

21. The device of claim 19, wherein the photodetector further comprises a buffer layer disposed between the photodetector active region and the third electrode.

22. The device of claim 19, wherein the photodetector active region further comprises at least sixteen alternating layers of copper phthalocyanine (CuPc) and 3,4,9,10-perylenetetracarboxylic bis-benzimidazole (PTCBI).

23. The device of claim 19, wherein the photodetector active region further comprises at least eight alternating layers of copper phthalocyanine (CuPc) and 3,4,9,10-perylenetetracarboxylic bis-benzimidazole (PTCBI).

24. The device of claim 19, wherein the photodetector active region further comprises a single bilayer of copper phthalocyanine (CuPc) and 3,4,9,10-perylenetetracarboxylic bis-benzimidazole (PTCBI).

25. The device of claim 19, wherein the photodetector active region further comprises a transparent top electrode.

26. The device of claim 1, wherein the device is incorporated into a monitor.

27. The device of claim 1, wherein the device is incorporated into a bistable switch.

28. The device of claim 1, wherein the device incorporated into an electronic paper.

29. The device of claim 1, wherein the device is incorporated into an electronic blackboard.

30. The device of claim 1, wherein the photodetector is inorganic.

31. The device of claim 1, wherein the photodetector is disposed under the organic light emtting device.

32. The device of claim 31, wherein the photodetector is a silicon diode fabricated on a silicon backplane.

33. A device, comprising:
an organic light emitting device adapted to emit light;
an organic photodetector disposed adjacent to the organic light emitting device, the organic photodetector adapted to detect the light emitted from the organic light emitting device, and
a feedback circuit connected to the organic light emitting device and the organic photodetector, the feedback circuit being adapted to adjust the current passing through the organic light emitting device based on the light detected by the organic photodetector.

34. The device of claim 33, wherein the organic light emitting device is off when the device is in a low state.

35. The device of claim 33, wherein the light transmitted by the organic light emitting device is directly coupled into the photodetector through the transparent electrode when the device is in a high state.

36. The device of claim 33, wherein the feedback circuit is external.

37. The device of claim 33, wherein the feedback circuit is an internal linear circuit.

38. A device, comprising:
a first electrode further comprising indium-tin-oxide (ITO);
an organic light emitting layer further comprising:
a layer of 4,4′-[N-(1-naphthyl)-N-phenyl-amino]biphenyl (α-NPD) disposed over the first electrode;
a layer of fac tris(2-phenylpyridine) iridium [Ir(ppy)₃] doped into a 4,4′-N,N′-dicarbazole-biphenyl (CBP) host disposed over the layer of α-NPD;
a layer of bathocuproine (BCP) disposed over the layer of CBP: Ir(ppy)₃;
a layer of tris(8-hydroxyquinoline) aluminum (Alq₃) disposed over the layer of BCP;
a second electrode further comprising:
a layer of Mg:Ag disposed over the organic light emitting layer;
a layer of ITO disposed over the layer of Mg:Ag;
an organic light detecting layer further comprising:
a layer of 4,4′,4″-tris(3-methyl-phenyl-phenyl-amino)triphenylamine (MTDATA) doped with two weight percent tetrafluoro-tetracyano-quinodimethane (F₄-TCNQ) disposed over the second electrode;
layers of CuPc, alternating with layers of 3,4,9,10-perylenetetracarboxylic bis-benzimidazole (PTCBI), disposed over the layer of MTDATA: F₄-TCNQ (2%);
a layer of bathocuproine (BCP) disposed over CuPc and PTCBI; and
a third electrode further comprising A1.
